(19) United States
(12) Patent Application Publication
(10) Pub. No.: US 2016/0218308 A1
(43) Pub. Date: Jul. 28, 2016

(54) PHOTOVOLTAIC DEVICE

(71) Applicant: DYESOL LTD, Queanbeyan, New South Wales (AU)

(72) Inventors: Hans DESILVESTRO, Shamrock Park, Manukau (NZ); Zhihong CAI, Chester (GB); Nancy Lan JIANG, Crestwood, NSW (AU)

(21) Appl. No.: 14/915,995

(22) PCT Filed: Sep. 4, 2014
(86) PCT No.: PCT/AU2014/000878

§ 371 Date: Mar. 2, 2016

(30) Foreign Application Priority Data
Sep. 4, 2013 (AU) 2013903369

(51) Int. Cl. H01L 51/42; H01L 51/00

(52) U.S. Cl. CPC H01L 51/4226; H01L 51/422; H01L 51/0003; H01L 2031/0344

(57) ABSTRACT

Photovoltaic devices are described including: a region of perovskite material which is in electrical contact with a mesoporous region of hole transport material, wherein the hole transport material is at least partially comprised of an inorganic hole transport material.

### TECHNICAL FIELD

This invention relates to photovoltaic devices and methods for preparing photovoltaic devices. This invention relates in particular to the internal architecture of solid state solar cells based on perovskite light absorbers and an inorganic hole transport material.

### BACKGROUND ART

Electricity production from solar energy through photovoltaic devices holds great promise for a future with less reliance on fossil fuels. Prior art photovoltaic technology is generally based on materials, which require large amounts of energy for their production, due to processing high temperature, often in excess of 1,000° C., due to very high demands in terms of purity and due the necessity of expensive, energy intensive and relatively slow high vacuum processing for some of the production steps. More recently, dye solar cell technology has been developed based on liquid organic electrolytes. While the latter technology is based on much lower temperature and much lower cost and faster processing steps, dye solar cell devices had only limited success in the market place, largely due to challenges with liquid organic electrolytes in terms of device sealing and high temperature stability. Therefore solid-state dye solar cells based on organic hole conductor materials have attracted much development effort. Very recently, 15% efficiency has been reported by for a solar cell based on a perovskite light absorber and an organic hole transport material (J. Burschka et al., “Sequential deposition as a route to high-performance perovskite-sensitized solar cells,” Nature, vol. 499, pp. 316-319, 2013). Current perovskite based solar cell embodiments are based on two main cell configurations:

1) Fluorine doped tin oxide (FTO)/dense hole blocking layer/mesoporous metal oxide thin film scaffold/perovskite/organic hole transport material/metal back contact.

2) FTO/dense hole blocking layer/perovskite/organic hole transport material/metal back contact.

The first configuration generally relies on a multi-step process involving printing, sintering, dipping or spraying steps and the second configuration is based on a high vacuum deposition process. Both of these two configurations use organic hole transport materials such as 2,2′,7,7′-tetrakis[N,N-di(4-methoxypenyl)amino]-9,9′-spirobifluorene (spiro-MeOTAD), poly(3-hexylthiophene-2,5-diyl) (P3HT), poly[2,6-(4,4-bis-(2-ethylhexyl)-4H-cyclopenta [2,1-b;3,4-b′]dithiophene-alt-4,7(2,1,3-benzothiadiazole)] (PCPDTBT) or poly[bis(4-phenyl)(2,4,6-trimethylphenyl)amine] (PTAA)), etc. Generally, such organic hole transport materials are difficult to synthesise and purify and therefore costly. Thus, neither of the prior art configurations 1) and 2) are based on low cost materials and low cost and minimum energy processes.

Organic hole transport materials tend to be sensitive to the higher temperatures experienced by solar devices (85° C. and higher on hot sunny days) and/or to UV irradiation, which can negatively impact a device's long term stability. Some organic hole transport materials are affected by atmospheric humidity and/or oxygen. Since organic hole transport materials show normally only relatively low hole mobilities and conductivities (below 10⁻⁶ S/cm, Snaith et al, “Enhanced charge mobility in a molecular hole transporter via addition of redox inactive ionic dopant: Implication to dye-sensitized solar cells,” Applied Physics Letters, vol. 89, p. 262114, 2006), additives such as lithium salts, 4-tert-butylpyridine (TBP) and dopants, e.g. cobalt complexes, need to be added to the hole transport material in order to achieve high device performance. Such additives unfavourably increase materials and processing costs and can result in lower device stability. TBP is toxic and a liquid with a boiling point below 200° C. Additionally, some of the additives, cobalt complexes in particular, lead to parasitic light absorption, which reduces the efficiency of a photovoltaic device.

Low conductivity (i.e. low hole mobility) of organic hole transport materials increases the solar device series resistance and leads to higher electron-hole recombination. Both effects result in lower device performance.

### SUMMARY OF THE INVENTION

In a first aspect the present invention provides a photovoltaic device including: a region of perovskite which is in electrical contact with a mesoporous region of hole transport material, wherein the hole transport material is at least partially comprised of an inorganic hole transport material.

Optionally, the inorganic hole transport material includes an oxide hole transport material.

Optionally, the inorganic hole transport material is a semiconductive material.

Optionally, the inorganic hole transport material is a p-type semiconductive material.

Optionally, the hole transport material is at least partially comprised of an organic hole transport material.

Optionally, the inorganic hole transport material is provided in a layer with a thickness of between about 100 nm to about 20 μm

Optionally, the inorganic hole transport material is provided in a layer with a thickness of between about 150 nm to about 1000 nm.

Optionally, the inorganic hole transport material is provided in a layer with a thickness of between about 200 nm to about 500 nm.

Optionally, the inorganic hole transport material is provided in a layer with a thickness of between about 10 nm to about 500 nm.

Optionally, the inorganic hole transport material includes NiO, Cu₂O, CuO, CuZO₂, with Z including, but not limited to Al, Ga, Fe, Cr, Y, Sc, rare earth. elements or any combination thereof, AgCoO₂ or other oxides, including delafossite structure compounds.

Optionally, the perovskite material is of formulae A₁₊ₓMX_{3-z}, ANX_{4-z}, A₂MX_{4-z}, A₃M₂Y_{7-2z} or A₄M₃X_{10-3z}.

Optionally, M is a mixture of monovalent and trivalent cations.

Optionally, the region of perovskite material comprises additives containing surface attaching groups such as but not limited to carboxylic or phosphonate groups.

Optionally, the perovskite material includes a homogeneous or heterogeneous mixture or layer-by-layer or side-by-side combination of two or more perovskite materials.

Optionally, the photovoltaic device comprises a cathode contact layer.

Optionally, the cathode contact layer comprises carbon.

Optionally, the cathode contact layer comprises aluminium, nickel, copper, molybdenum or tungsten.

Optionally, the photovoltaic device further includes an electron blocking layer between the region of hole transport material and the cathode contact layer.

Optionally, the photovoltaic device further includes an electron blocking layer between the region of perovskite material and the cathode contact layer.

Optionally, the photovoltaic device further includes a scaffold layer which provides a high surface area substrate for the perovskite material.

Optionally, the photovoltaic device comprises an anode contact layer.

Optionally, the photovoltaic device further includes a hole blocking layer between a scaffold layer and the anode contact layer.

Optionally, the photovoltaic device further includes a hole blocking layer between the region of perovskite material and the anode contact layer.

Optionally, the photovoltaic device further includes a polymeric or ceramic porous separator layer between the region of hole transport material and the scaffold layer.

Optionally, the perovskite material is intermixed with at least a region of one of a scaffold, a porous separator layer and/or the hole transport material.

Optionally, the perovskite material is intermixed with at least a region of one of a scaffold, a porous separator layer, the hole transport material and/or a cathode contact layer.

Optionally, at least a region of the hole transport material is intermixed with at least a region of a cathode contact layer and the perovskite material is intermixed with at least a region of one of a scaffold, a porous separator layer, the intermixed hole transport material and/or a cathode contact layer.

Optionally, the photovoltaic device comprises a substrate.

Optionally, the substrate is a metal or metal foil.

In a second aspect the invention provides a method of forming a photovoltaic device according to any preceding claim including the steps of: preparing first and second sub-assemblies; applying the perovskite material in a liquid preparation to at least one of the sub-assemblies; and bringing the sub-assemblies together.

Optionally, one of the subassemblies comprises a substrate, optionally an electron blocking layer, a carbon-based cathode contact layer and optionally a region of hole transport material.

Optionally, one of the subassemblies comprises a substrate, optionally an electron blocking layer, a region of hole transport material and optionally a porous separator layer.

Embodiments of the present invention use an inorganic hole transport material, preferably an oxide hole transport material in solar cells based on perovskite light absorbers. Oxide hole transport materials present the potential of completely inorganic mesoporous or bulk heterojunction solar cells, which are expected to offer higher stability, especially above 80° C., compared to organic materials. Oxide hole transport materials can be used in at least five solid state solar cell configurations, which will be detailed in the following. Preferred light absorbers are of ambipolar nature, where hole and electron transport rates are comparable. Such materials can be regarded as close to intrinsic (i) semiconductors.

Embodiments of the present invention provide specific cell configurations, where the transparent character of inorganic hole transport materials disclosed hereunder, can be utilised to direct light toward the light absorber layer, while providing effective conduction paths for photogenerated holes.

Embodiments of the present invention provide methods for preparing photovoltaic devices through processes suitable for mass manufacture. Oftentimes, inorganic materials require different processing steps for ink, slurry or paste preparation, for applying such media, particularly if creation of interpenetrating networks is desired and for annealing and/or sintering of any such layers applied.

Additional embodiments are also disclosed based on mixed inorganic/organic hole transport materials. Such hybrids can offer advantages of ease of production for organic or polymeric hole transport materials, in combination with the much higher hole mobility of inorganic hole transport materials and without the requirement of expensive, toxic and/or volatile additives.

Since most oxide hole transport materials have much higher conductivities than organic hole transport materials, series resistance and electron-hole recombination can be reduced, resulting in higher light-to-electricity conversion efficiency for solar devices.

Embodiments of the invention provide solar cells, which are based on low cost, inorganic materials of low toxicity, high stability which are easy to manufacture and process through low energy processes.

### BRIEF DESCRIPTION OF THE DRAWINGS

FIG. 1 shows a schematic cross section through an embodiment according to the present invention.

FIG. 2 shows a schematic cross section through a preferred embodiment according to the present invention.

FIG. 3 shows a schematic cross section through an alternative embodiment according to the present invention.

FIG. 4 shows a schematic cross section through another alternative embodiment according to the present invention.

FIG. 5 shows a schematic cross section through another alternative embodiment according to the present invention.

FIG. 6 shows a schematic cross section through another alternative embodiment according to the present invention.

FIG. 7 shows 1 sun IV curves for Example 2.

FIG. 8 shows 1 sun IV curve for Example 3.

FIG. 9 shows 1 sun IV curve for Example 4.

### DETAILED DESCRIPTION OF THE INVENTION

While this invention is capable of embodiment in many different forms, there is shown in the drawings and will herein be described in detail, several specific embodiments with the understanding that the present disclosure is to be considered as an exemplification of the principles of the invention and is not intended to limit the invention to the embodiments so illustrated. With the exception of specific examples provided, any description of A/B/C/etc. configurations does generally not indicate the sequence of production steps, which may be A/B/C/etc. or, alternatively, etc./C/B/A. The term “cathode” is used hereunder for the pole which provides electrons to the photoactive layer, i.e. for the positive pole, whereas the term “anode” is used for the pole which collects electrons from the photoactive layer, i.e. for the negative pole. Preferred embodiments according to this invention comprise at least one substrate, either a cathode or an anode substrate.

Five representative device configurations according to the present invention will be disclosed hereunder.

Device Configuration 1:

Device configuration 1 is schematically shown in FIG. 1. Cathode substrate (1) is preferably transparent and consists of glass or polymer, where both can either be rigid or flexible.

Optionally, cathode substrate (1) can be opaque and be based on a metal including but not limited to steel, aluminium, nickel, copper, molybdenum, tungsten or can be based on a metal, which is at least partially covered with an insulating film.

Cathode contact layer (2) is in mechanical contact with the cathode substrate (1) and consists of at least one type of conductor with a work function closely matching the p-type hole transport material's valence band level, including, but not limited to delafossite-type oxides, fluorine (FTO) or indium (ITO) doped tin oxide, aluminium doped zinc oxide (AZO), various forms of carbon, including but not limited to carbon black, graphite, graphene, carbon nanotubes, doped or undoped conductive polymers or thin layers of Ni, Au, Ag, Ir or Pt. Preferably, cathode contact layer is a transparent conductive coating on top of substrate (1). Optionally, cathode contact and current collector materials, electrically associated with cathode contact layer (2), can be surface treated, e.g. through exposure to plasma and/or ozone and/or chemically modified by high work function materials such as small amounts of noble metals.

Cathode contact layer (2) can be applied to cathode substrate (1) by any method known to those skilled in the art including, but not limited to chemical or physical vapour deposition, electroless plating, sol gel coating or any coating, printing, casting or spraying technique.

The cathode contact layer (2) can be applied to the substrate homogeneously or in a patterned way. Optionally, cathode contact layer (2) can be rendered more conductive through electrodeposition. A thermal annealing or sintering step may follow deposition of contact layer (2).

Optional electron blocking layer (3) is in electrical contact with cathode contact layer (2) and preferably consists of a dense p-type ultrathin oxide semiconductor layer, which is preferably not thicker than 100 nm. The electron blocking layer (3) blocks charge recombination and is also often referred to as hole extraction layer. It can be based on a p-type oxide semiconductor, such as NiO or CuAlO₂ or any organic or inorganic hole extraction material employed in related fields such as organic photovoltaics or light emitting diodes such as MoO₃, WO₃, V₂O₅, CrOₓ, Cu₂S, BiI₃, PEDOT:PSS, TPD (N,N′-bis(3-methylphenyl)-N,N′-bis(phenyl)-benzidine), poly-TPD, spiro-TPD, (N,N′-bis(naphthalen-2-yl)-N,N′-bis(phenyl)-benzidine), spiro-NPB, TFB (poly[(9,9-dioctylfluorenyl-2,7-diyl)-co-(4,4′-(N-(4-sec-butylphenyl) diphenylamine)]), polytriarylamine, poly(copper phthalocyanine), rubene, NPAPF (9,9-bis[4-(N,N-bis-naphthalen-2-yl-amino)phenyl]-9H-fluorene. The doping level of the blocking layer material may be higher (p⁺) than the doping level of the subsequent layer of porous p-doped material, thereby facilitating hole extraction from the device. A combination of p+ electron blocking layer with a p-type hole conductor material will be referred to as a p⁺/p combination.

Electron blocking layer (3) can be applied to the cathode contact layer (2) by any method known to those skilled in the art, including, but not limited to chemical or physical vapour deposition, atomic layer deposition (ALD), sol gel coating, electrochemically induced surface precipitation or any coating, printing, casting or spraying technique. A thermal annealing or sintering step may follow deposition of electron blocking layer (3).

Inorganic bole transport material layer (4) is in in electrical contact with cathode contact layer (2), preferably through an electron blocking layer (3) positioned between cathode contact layer (2) and hole transport material layer (4). Hole transport material layer (4) consists preferably of a porous and more preferably a mesoporous layer of a semiconductive material and most preferably of a mesoporous p-type oxide semiconductor layer. Such a layer can be formed by interconnecting p-type oxide semiconductor nanoparticles of chemically and photochemically highly stable compounds including, but not limited to NiO, Cu₂O, CuO, CuZO₂, wherein Z includes, but is not limited to Al, Ga, Fe, Cr, Y, Sc, rare earth elements or any combination thereof, AgCoO₂ or other oxides, including delafossite structure compounds. The most preferred materials are selected that the valence (VB) adequately matches the HOMO (=highest occupied molecular orbital) energy level of the light absorber according to equation [1],

E_{VB}<˜E_{HOMO} [1],

where E stands for the potential in V. In preferred embodiments of this invention, the inorganic hole transport material forms a transparent, translucent or semi-opaque thin film and is characterised by a band gap of higher than 2.5 eV, more preferably higher than 2.9 eV and most preferably higher than 3.1 eV. Preferred mesoporous layer thickness is from 100 nm to 20 μm, more preferably from 150 nm to 1000 nm and most preferably from 200 nm to 500 nm.

Inorganic hole transport material layer (4) can be applied to the electron blocking layer (3) or optionally directly to the cathode contact layer (2) by any method known to those skilled in the art including, but not limited to sol gel coating, electrochemically induced surface precipitation or any coating, printing, casting or spraying technique of a medium containing preferably a nanoparticulate p-type oxide and optionally binders, surfactants, emulsifiers, levelers and other additives to aid with the coating process. A thermal annealing, burn-out or sintering step may follow deposition of inorganic hole transport material layer (4).

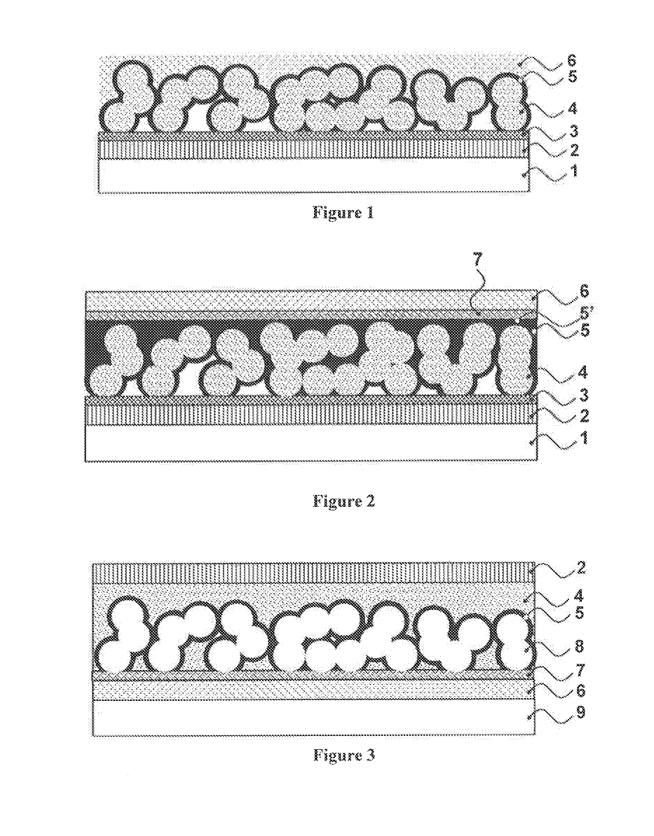

A region of perovskite in the form of a thin continuous or discontinuous layer of perovskite (5) light absorber is in electrical contact with a region of hole transport material layer (4) with the layer thickness of the former reaching from a few nanometers to several hundred nanometers. In a preferred embodiment according to the present invention, schematically shown in FIG. 2, a capping layer (5′) of light absorber material extends beyond the porous hole transport material layer (4) by preferably 20-100 nm. The perovskite layer (5) comprises at least one type of perovskite layer, as a monolayer, as discrete nano-sized particles or quantum dots or as a continuous or quasi-continuous film, which fully or partly fills the pores of the inorganic hole transport material layer (4) in order to form an at least partially interpenetrating network. A homogeneous or heterogeneous mixture or layer-by-layer or side-by-side combination of two or more perovskite materials of formulae A₁₊ₓMX_{3-z}, ANX_{4-z}, A₂MX_{4-z}, A₃M₂X_{7-2z} or A₄M₃X_{10-3z} can optionally be employed to absorb light of different wavelengths from the solar spectrum. A represents at least one type of inorganic or organic monovalent cation including but not limited to Cs⁺, primary, secondary, tertiary or quaternary organic ammonium compounds, including nitrogen-containing heterorings and ring systems. Optionally, said cation can be divalent, in which case A stands for A_{0.5}. M is a divalent metal cation selected from the group consisting of C²⁺, Ni²⁺, Co²⁺, Fe²⁺, Mn²⁺, Cr²⁺, Pd²⁺, Rh²⁺, Ru²⁺, Cd²⁺, Ge²⁺, Sn²⁺, Pb²⁺, Eu²⁺, Yb²⁺, or from other transition metals or rare earth elements. Alternatively, M is a mixture of monovalent and trivalent cations including but not limited to Cu⁺/Ga³⁺, Cu⁺/In³⁺, Cu⁺/Sb³⁺, Ag⁺/Sb³⁺, Ag⁺/Bi³⁺ or other combinations between Cu⁺, Ag⁺, Pd⁺, Au⁺ and a trivalent cation selected from the group of Bi³⁺, Sb³⁺, Ga³⁺, In³⁺, Ru³⁺, Y³⁺, La³⁺, Ce³⁺ or any transition metal or rare earth element. N is selected from the group of Bi³⁺, Sb³⁺, Ga³⁺, In³⁺ or a trivalent cation of a transition metal or rare earth element. In certain embodiments according to this invention, M or N comprise a multitude of metallic, semimetallic or semiconductive, such as Si or Ge, elements. Thus M in above formulae is replaced by

M1_{y1}M2_{y2}M3_{y3} . . . Mn_{yn}

or N in above formula is replaced by

N1_{y1}N2_{y2}N3_{y3} . . . Nn_{yn};

wherein the average oxidation number of each metal Mn is OX#(Mn) or the average oxidation number of each metal Nn is OX#(Nn) and wherein

y1+y2+y3+ . . . +yn=1.

n is any integer below 50, preferably below 5. The average oxidation state of the multi-element component (M1_{y1}M2_{y2}M3_{y3} . . . Mn_{yn}) is then given by

OXₐᵥₑ(M)=y1×OX#(M1)+y2×OX#(M2)+y3×OX#(M3)+ . . . +yn×OX#(Mn)

OX_{avg}(M) is preferably higher than 1.8 and lower than 2.2, more preferably higher than 1.9 and lower than 2.1 and most preferably higher than 1.95 and lower than 2.05.

Correspondingly, the average oxidation state of the multi-element component (N1_{y1}N2_{y2}N3_{y3} . . . Nn_{yn}) is given by

OX_{avg}(N)=y1×OX#(N1)+y2×OX#(N2)+y3×OX#(N3)+ . . . +yn×OX#(Nn)

OX_{avg}(N) is preferably higher than 2.8 and lower than 3.2, more preferably higher than 2.9 and lower than 3.1 and most preferably higher than 2.95 and lower than 3.05.

The three or four X are independently selected from Cl⁻, Br⁻, I⁻, NCS⁻, CN⁻, and NCO⁻.

Preferred perovskite materials are of ambipolar nature. Therefore they act not only as light absorbers, hut, at least partially, as hole and electron transport materials, x and z are preferably close to zero, In order to achieve a certain level of n- or p-doing for certain embodiments according to this invention, the perovskite compound may be nonstoichiometric to some degree and, thus, x and/or z may optionally be adjusted between 0.1 and −0.1.

A, M, N and X are selected in terms of their ionic radii that the Goldschmidt tolerance factor is not larger than 1.1 and not smaller than 0.7. In preferred embodiments the Goldschmidt tolerance factor is between 0.9 and 1 and the perovskite crystal structure is cubic or tetragonal. In optional embodiments according to this invention, the perovskite crystal structure can be orthorhombic, rhombohedral, hexagonal or a layered structure. In preferred embodiments, the perovskite crystal structure displays phase stability between at least −50° C. and +100° C.

A thin continuous or discontinuous layer of perovskite (5) can be applied to hole transport material layer (4) through a wet chemistry one step, two step or multi-step deposition process involving dipping, spraying, coating, including but not limited to slot die coating, or printing, such as ink jet printing. Optionally, consecutive layers can be built up through a SILAR technique (successive ionic layer adsorption and reaction). Such methods allow for controlled assembly of core-shell structures. Optionally, a preassembly containing porous inorganic hole transport material layer (4) is placed under vacuum or partial vacuum in order to facilitate pore filling. Optionally, some excess perovskite solution is removed, e.g. through a squeegee. A thermal annealing or sintering step may follow deposition of perovskite layer (5).

In alternative embodiments according to the present invention, perovskite is applied to individual particles of the hole transport material prior to forming a combined hole transport material/perovskite layer.

Anode contact layer (6) is a conductor layer in electrical contact with the perovskite layer (5), preferably with the perovskite capping layer (5′), and providing electron collection. The conductive material can be any material with good electrical conductivity and a work function (or conduction band) adequately matching the light absorber's LUMO (=lowest unoccupied molecular orbital) according to equation [2]. Conductors include but are not limited to Al, Ga, In, Sn, Zn, Ti, Zr, Mo, W, steel, doped or undoped conductive polymers, or any alloy with a work function (or conduction band level) fulfilling equation [2],

E_{CR or WF}>E_{LUMO} [2],

where E stands for the potential in V. Alloys include but are not limited to alloyed steel or MgAg.

Anode contact layer (6) can be applied to perovskite layer (5) by any method known to those skilled in the art, including, but not limited to chemical or physical vapour deposition, electroless plating or any coating, printing or spraying technique. The anode contact layer can be applied to perovskite layer (5) homogeneously or in a patterned way. Optionally, anode contact layer (6) can be rendered more conductive through electrodeposition of the same or a different conductor, following deposition of a thinner seed anode contact layer. A thermal annealing or sintering step may follow deposition of anode contact layer (6).

Optionally, a hole blocking layer (7) such as a dense n-type TiO₂ or ZnO film or a film of PCBM ([6,6]-phenyl-C61-butyric acid methyl ester) is applied between layers (5) and (6).

Such an embodiment is detailed schematically in FIG. 2.

Optional hole blocking layer (7) can be applied by any method known to those skilled in the art including, but not limited to chemical or physical vapour deposition, atomic layer deposition (ALD), sol gel coating, electrochemically induced surface precipitation or any coating, printing or spraying technique. A thermal annealing or sintering step may follow deposition of hole blocking layer (7).

The optional hole blocking layer (7) can optionally be applied directly to the inner surface of anode contact material (6), such as Al foil, preferably through a process, where temperatures are not higher than 250° C., or where the annealing step occurs very rapidly, e.g. through rapid thermal annealing. Alternatively, a hole blocking layer which can be processed at lower temperatures, such as PCBM ([6,6]-phenyl-C61-butyric acid methyl ester) can be employed.

Subsequently, the Al/hole blocking layer subassembly may be combined with the subassembly comprising cathode substrate (1), cathode contact layer (2), optional electron blocking layer (3), hole transport layer (4) and perovskite layer (5). The latter is preferably still wet and optionally contains means to facilitate surface attachment between the perovskite and the hole blocking layer (7) or anode contact material (6). Said means can consist in additives containing surface attaching groups such as carboxylic or phosphonate groups or binders on the basis of cellulose, styrene butadiene, polyacrylonitrile, PVdF or any other binder or crosslinking agent known to those skilled in the art.

In another embodiment according to the present invention, a liquid film containing perovskite can be pre-applied to anode contact material (6) or to the surface of optional thin hole blocking layer (7), where the liquid's viscosity and surface tension is adjusted adequately to allow for controlled processing such as roll-to-roll processing. Anode contact material (6) in this embodiment can be a foil, with its surface optionally roughened mechanically or through chemical or electrochemical etching. In order to facilitate removal of any processing solvents, a woven or non-woven mesh, a conductive felt or foam or an at least, partially perforated foil can be employed.

Depending on the nature of the substrates and other device components, light can be directed into a device of configuration 1 from the anode or the cathode side, if none of the substrates is opaque the device can be operated as a bifacial device, i.e. it can collect and convert light impinging from the anode and the cathode side. Alternatively, one of the substrates can be opaque such as optionally insulated steel, aluminium, nickel, molybdenum or concrete.

For substantially undoped light absorbers configuration I devices can be described as pₘ/aᵢ devices, where m indicates the preferably mesoporous nature of the p-type material.

Considering optional electron blocking (p or p⁺) and/or hole blocking layers (n or n⁺), preferred device configuration 1, not including electrical contacts, can be described as:

(p⁽⁺⁾/pₘ/aᵢ/(n⁽⁺⁾) [3];

where parentheses indicate optional elements or optionally higher doping levels.

In alternative embodiments according to the present invention, a certain degree of light absorber n-doping (aₙ) or p-doping (aₚ) may be beneficial. Considering optional electron blocking (p or p⁺) and/or hole blocking layers (n or n⁺), alternative device configuration 1, not including electrical contacts, can be described as:

(p⁽⁺⁾/pₘ/aₙ or aₚ/(n⁽⁺⁾) [4]

Device Configuration 2:

Device configuration 2 is schematically shown in FIG. 3. A key difference to device configuration 1 is the presence of a scaffold (8). The function of the scaffold is to provide a high surface area substrate for the application of the light absorber. High internal scaffold area provides for thin light absorber layers, where the total amount of light absorber material is defined by the amount of light which needs to be absorbed in order to fulfil the device's power specifications. Thin light absorber layers provide for more effective charge (electron-hole) separation and generally lead to lower electron-hole recombination and thereby to higher device performance. In contrast to device configuration 1, where the hole transport layer (4) fulfils the role of providing a large surface area substrate for the light absorber layer, device configuration 2 decouples the functions of hole conduction and high internal surface area scaffold. Preferred scaffold (8) is porous and, more preferably mesoporous, based on an oxide material and most preferably based on a n-type semiconductor oxide, which is in electrical contact with anode contact layer (6) associated with anode substrate (9) or, optionally, with hole blocking layer (7). Preferred semiconductors are chemically and photochemically highly stable and are characterised by a band gap of preferably higher than 2.5 eV, more preferably higher than 2.9 eV and most preferably higher than 3.1 eV. Preferred semiconductors include but are not limited to TiO₂, ZnO, Al₂O₃, Nb₂O₅, WO₃, In₂O₃, Bi₂O₃, Y₂O₃, Pr₂O₃, CeO₂ and other rare earth metal oxides, MgTiO₃, SrTiO₃, BaTiO₃, Al₂TiO₅, Bi₄Ti₃O₁₂ and other titanates, CaSnO₃, SrSnO₃, BaSnO₃, Bi₂Sn₃O₉, Zn₂SnO₄, ZnSO₃ and other stannates, ZrO₂, CaZrO₃, SrZrO₃, BaZrO₃, Bi₃Zr₃O₁₂ and other zirconates, combinations of two or more of the aforementioned and other multi-element oxides containing at least two of alkaline metal, alkaline earth metal elements, Al, Ga, In, Si, Ge, Ph, Sb, Bi, Sc, Y, La or any other lanthanide, Ti, Zr, Hf, Nb, Ta, Mo, W, Ni or Cu.

Optionally, the scaffold material can be doped with metallic or non-metallic additives or surface modified by a thin layer of oxide metals, semimetals and semiconductors including but not limited to Ti, Zr, Al, Mg, Y, Nb.

A region of thin continuous or discontinuous layer of perovskite (5), is in electrical contact with a region of hole transport material layer (4) and in mechanical contact with scaffold (8).

In a preferred embodiment, said layer of perovskite (5) is additionally in electrical contact with scaffold (8). The hole transport material layer (4) thickness is preferably between a few nanometers to several hundred nanometers. The perovskite layer comprises at least one type of perovskite layer, as a monolayer, as discrete nano-sized particles or quantum dots or as a continuous or quasi-continuous film, which fully or partly fills the pores of the scaffold (8) and/or the inorganic hole transport material layer (4) in order to form an at least partially interpenetrating network with the scaffold (8) and/or the hole transport material layer (4). A homogeneous or heterogeneous mixture or layer-by-layer or side-by-side combination of two or more perovskite materials of formulae A₁₊ₓMX_{3-z}, ANX_{4-z}, A₂MX_{4-z}, A₃M₂X_{7-2z} or A₄M₃X_{10-3z} can optionally be employed to absorb light of different wavelengths from the solar spectrum. A represents at least one type of inorganic or organic monovalent cation including but not limited to Cs⁺, primary, secondary, tertiary or quaternary organic ammonium compounds, including nitrogen-containing heterorings and ring systems.

Optionally, said cation can be divalent, in which case A is standing for A_{0.5}. M is a divalent metal cation selected from the group consisting of Cu²⁺, Ni²⁺, Co²⁺, Fe²⁺, Mn²⁺, Cr²⁺, Pd²⁺, Rh²⁺, Ru²⁺, Cd²⁺, Ge²⁺, Sn²⁺, Pb²⁺, Eu²⁺, Vb²⁺, or from other transition metals or rare earth elements. Alternatively, M is a mixture of monovalent and trivalent cations including but not limited to Cu⁺/Ga³⁺, Cu³⁰ /In³⁺, Cu⁺/Sb³⁺, Ag⁺/Sb³⁺, Ag⁺/Bi³⁺ or other combinations between C⁺, Ag⁺, Pd⁺, Au⁺ and a trivalent cation selected from the group of Bi³⁺, Sb³⁺, Ga³⁺, In³⁺, Ru³⁺, Y³⁺, La³⁺, Ce³⁺ or any transition metal or rare earth element. N is selected from the group of Bi³⁺, Ga³⁺, In³⁺ or a trivalent cation of a transition metal or rare earth element.

In certain embodiments according to this invention, M or N comprise a multitude of metallic, semimetallic semiconductive, such as Si or Ge, elements. Thus M in above formulae is replaced by

M1_{y1}M2_{y2}M3_{y3} . . . Mn_{yn}

or N in above formula is replaced by

N1_{y1}N2_{y2}N3_{y3} . . . Nn_{yn};

wherein the average oxidation number of each metal Mn is OX#(Mn) or the average oxidation number of each metal Nn is OX#(Nn) and wherein

y1+y2+y3+ . . . +yn=1.

n is any integer below 50, preferably below 5. The average oxidation state of the multi-element component (M1_{y1}M2_{y2}M3_{y3} . . . Mn_{yn}) is then given by

OX_{avg}(M)=y1×OX#(M1)+y2×OX#(M2)+y3×OX#(M3)+ . . . +yn×OX#(Mn)

OX_{avg}(M) is preferably higher than 1.8 and lower than 2.2, more preferably higher than 1.9 and lower than 2.1 and most preferably higher than 1.95 and lower than 2.05.

Correspondingly, the average oxidation state of the multi-element component (N1_{y1}N2_{y2}N3_{y3} . . . Nn_{yn}) is given by

OXₐᵥₑ(N)=y1×OX#(N1)+y2×OX#(N2)+y3×OX#(N3)+ . . . +yn×OX#(Nn)

OX_{avg}(N) is preferably higher than 2.8 and lower than 3.2, more preferably higher than 2.9 and lower than 3.1 and most preferably higher than 2.95 and lower than 3.05.

The three or four X are independently selected from Cl⁻, Br⁻, I⁻, NCS⁻, CN⁻, and NCO⁻.

Preferred perovskite materials are of ambipolar nature. Therefore they act not only as light absorbers, but, at least partially, as hole and electron transport materials, x and z are preferably close to zero. In order to achieve a certain level of n- or p-doping for certain embodiments according to this invention, the perovskite compound may be nonstoichiometric to some degree and, thus, x and/or z may optionally be adjusted between 0.1 and −0.1.

A, M, and X are selected in terms of their ionic radii that the Goldschmidt tolerance factor is not larger than 1.1 and not smaller than 0.7. In preferred embodiments the Goldschmidt tolerance factor is between 0.9 and 1 and the perovskite crystal structure is cubic or tetragonal, in optional embodiments according to this invention, the perovskite crystal structure can be orthorhombic, rhombohedral, hexagonal or a layered structure. In preferred embodiments, the perovskite crystal structure displays phase stability between at least −50° and +100° C.

A thin continuous or discontinuous layer of perovskite (5) can be applied to scaffold (8) through a wet chemistry one step, two step or multi-step deposition process involving dipping, spraying, coating or printing, such as ink jet printing. Optionally, consecutive layers can be built up through a SILAR technique (successive ionic layer adsorption and reaction).

Such methods allow for controlled assembly of core-shell structures. Optionally, a preassembly containing scaffold (8) is placed under vacuum or partial vacuum in order to facilitate pore filling. Optionally, some excess perovskite solution is removed, e.g. through a squeegee. A thermal annealing or sintering step may follow deposition of perovskite layer (5).

In alternative embodiments according to the present invention, perovskite is applied to individual particles of the scaffold material prior to forming a combined scaffold/perovskite layer.

Importantly, the device contains no additives such as Li salts, cobalt complexes or TBP, The mesoporous hole transport material consists preferably, but not necessarily, of nano-sized p-type oxide semiconductor particles of NiO, Cu₂O, CuO, CuZO₂, with Z including, but not limited to Al, Ga, Fe, Cr, Y, Sc, rare earth elements or any combination thereof, AgCoO₂ or other oxides, including delafossite structure compounds, selected that the valence (VB) adequately matches the HOMO energy level of the light absorber according to relation [1]. In preferred embodiments of this invention, said p-type oxide semiconductor forms a transparent, translucent or semi-opaque thin film and is characterised by a band gap of higher than 2.5 eV, more preferably higher than 2.9 eV and most preferably higher than 3.1 eV.

Average particle size of the p-type semiconductor is preferably below 50 nm, more preferably between 1 and 20 nm and most preferably between 1 and 5 nm. For processing purposes said particles may be suspended in a mixture of solvent and binder according to many formulations known by those skilled in the art. Said mixture can be applied at least partly into the pores and/or on top of the scaffold perovskite preassembly by any spraying, casting, coating or printing technique.

In order to obtain optimum electrical contact between hole transport layer (4) and cathode contact layer (2), the former may be applied to the latter in a separate, optimized production step. In a specific embodiment according to the present invention, a mesoporous NiO film is applied to a cathode substrate (1) such as nickel, acting at the same time as the cathode contact material (2), with optionally a compact electron blocking layer (3), such as a nonporous NiO or MoO₃ layer, between cathode substrate (1) and hole transport material (4).

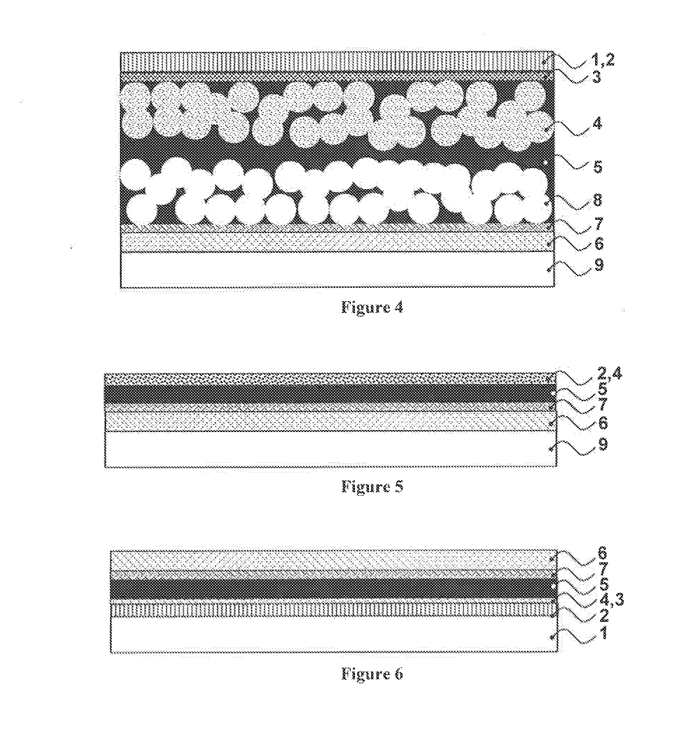

Such a pre-assembly can then be pre-wetted with perovskite solution and then be combined with a pre-assembly comprising at least scaffold (8) with its pores filled as well with perovskite solution and, optionally, all or some of anode substrate (9), anode contact layer (6), and/or hole blocking layer (7). An embodiment resulting from such a sequence of steps is schematically shown in FIG. 4. For generally better process control and device reliability, an inert polymeric or ceramic separator layer can optionally be spaced between hole transport material (4) layer and scaffold (8). The ceramic materials can be based on porous, preferably of mesoporous SiO₂, Al₂O₃ or ZrO₂. Cathode contact material (2) can optionally be a foil, with its surface optionally roughened mechanically or through chemical or electrochemical etching. In order to facilitate removal of any processing solvents, a woven or non-woven mesh, a conductive felt or foam or an at least partially perforated foil can be employed.

Depending on the nature of the substrates and other device components, light can be directed into a device of configuration 2 from the anode or the cathode side. If none of the substrates is opaque the device can be operated as a bifacial device, i.e. it can collect and convert light impinging from the anode and the cathode side. Alternatively, one of the substrates can be opaque such as optionally insulated steel or aluminium, nickel, molybdenum or concrete.

For substantially undoped light absorbers aᵢ, configuration 2 devices can be described as (n)ₘ/aᵢ/p₍ₘ₎, or equally as p₍ₘ₎/aᵢ/(n)ₘ devices, where in indicates the preferably mesoporous nature of the scaffold and optionally of the p-type material. Considering optional hole blocking (7) (n or n⁺) and/o electron blocking layers (3) (p or p⁺), preferred device configuration 2, not including electrical contacts, can be described as:

(n⁽⁺⁾/(n)ₘ/aᵢ/p₍ₘ₎/(p⁽⁺⁾) [5],

where parentheses indicate optional elements, optionally higher doping levels, or the optional n-type nature of the scaffold.

In an alternative embodiment according to the present invention, a certain degree of light absorber n-doping (aₙ) or p-doping (aₚ) may be beneficial. Considering optional hole blocking (n or n⁺) and/or electron blocking layers (p or p⁺), alternative device configuration 2, not including electrical contacts, can be described as:

(n⁽⁺⁾/(n)ₘ/aₙ or aₚ/p₍ₘ₎/(p⁽⁺⁾) [6]

### Device Configuration 3:

The purpose of this configuration is to combine favourable properties of oxide hole transport materials such as high hole conductivity in combination with favourable properties of organic hole transport materials (e.g. spiro-MeOTAD), such as solubility in certain solvents, which facilitates solvent processing and pore filling. By choosing a p-type inorganic material, which closely matches the valence band of the organic hole transport material's HOMO level, overall hole conductivity of the mixture or composite can be increased, when compared to that of an organic hole conductor material only. Therefore, levels of doping additives such as Li salts, cobalt complexes or TBP can be reduced or eliminated entirely. According to this invention, any mixture of inorganic and organic hole transport materials can be employed, as long as the hole transport material's HOMO or valence bands closely match each other and also favourably match the HOMO level of the light absorber.

Apart from the mixed organic and inorganic hole transport material layer (10) (not shown in drawings), which replaces (4) in FIG. 3 or FIG. 4 device 3 configuration is equivalent to device configuration 2 and the same materials and material combinations can be employed as disclosed for device configuration 2, resulting in the same types of devices [5] and [6].

### Device Configuration 4:

Device configuration 4 is schematically shown in FIG. 5. In contrast to device configurations 1-3, the perovskite layer (5) is not deposited onto a high surface area. porous scaffold (8) or hole conductor layer, but preferably as a dense or relatively dense thin film onto the substantially flat anode contact layer (6) or the optional hole blocking layer (7). Anode contact layer (6) can be based on fluorine (FTO) or indium (ITO) doped tin oxide, aluminium doped zinc oxide (AZO), Al or any other material, including alloys, which have a work function (or conduction band level) adequately matching light absorber LUMO according to equation [2], Optionally, anode contact layer (6) can be surface-modified, e.g. in a reducing atmosphere and/or with a low work function material. In another embodiment according to the present invention, anode contact material (6) can be surface modified to increase its surface roughness and effective surface area, thus providing a quasi-3D interface between anode contact layer (6), optionally coated with a hole blocking layer (7), and perovskite layer (5). The p-type oxide hole transport layer (4), deposited on top of the perovskite layer (5), is mesoporous. Since many p-type delafossite structure oxides are conductive enough for current collection, no additional cathode contact layer (2) may be required for the collection of the cathodic current. Some p-type delafossite structure oxides offer significant optical transparency and are therefore directly suitable as substantially transparent cathode contact layers, optionally applied to a substantially transparent cathode substrate consisting of glass or a polymer.

Depending on the nature of the substrates and other device components, light can be directed into a device of configuration 4 from the anode or the cathode side. If none of the substrates is opaque the device can be operated as a bifacial device, i.e. it can collect and convert light impinging from the anode and the cathode side. Alternatively, one of the substrates can he opaque such as optionally insulated steel, aluminium, nickel, molybdenum or concrete.

For substantially undoped light absorbers aᵢ, configuration 4 devices can be described as p/aᵢ devices. Considering optional hole blocking (n or n⁺) and/or electron blocking layers (p or p⁺), preferred device configuration 4, not including electrical contacts, can be described as:

(n⁽⁺⁾/aᵢ/p/(p⁽⁺⁾) [7],

where parentheses indicate optional elements or optionally high doping levels.

In an alternative embodiment according to the present invention, a certain degree of light absorber n-doping (aₙ) or p-doping (aₚ) may be beneficial. Considering optional hole blocking (n or n⁺) and/or electron blocking layers (p or p⁺), alternative device configuration 4, not including electrical contacts, can be described as:

(n⁽⁺⁾/aₙ or aₚ/p/(p⁽⁺⁾) [8]

### Device Configuration 5:

Device configuration 5 is schematically shown in FIG. 6. In contrast to device configurations 1-3, the perovskite layer (5) is preferably deposited as a dense or relatively dense, thin film onto the substantially flat, ultrathin inorganic mesoporous hole transport material layer (4), which is in preferred device configurations 5 embodiments not thicker than 100 nm and acts as an electron blocking layer (3). Anode contact layer (6) can be based on fluorine (FTO) or indium (ITO) doped tin oxide, aluminium doped zinc oxide (AZO), Al or any other material, including alloys, which have a work function (or conduction band level) adequately matching light absorber LUMO according to equation [2]. Optionally, anode contact layer (6) can be surface-modified, e.g. in a reducing atmosphere and/or with a low work function material. In another embodiment according to the present invention, anode contact material (6) can be surface modified to increase its surface roughness and effective surface area, thus providing a quasi-3D interface between anode contact layer (6), optionally coated with a hole blocking layer (7), then followed by a perovskite layer (5). As an example, high surface Al foil, such as used for electrolytic or double layer capacitors and commercially offered by Sam-A Aluminium Co., Ltd, or by JCC (Japan Capacitor Company) can be employed. Cathode contact layer (2) can be a p-type transparent conductive oxide (TCO), including but not limited to delafossite-structured oxides, various forms of carbon, including but not limited to carbon black, graphite, graphene, carbon nanotubes, Au, Ag, IPTO or any other material adequately matching light absorber HOMO according to equation [1]. Optionally, cathode contact layer (2) can be surface-modified, e.g. through ozone treatment and/or with a high work function material such as Pt or Au. Cathode contact layer (2) may be applied to a glass substrate (1). This configuration holds the potential of ultimately low costs of materials.

Depending on the nature of the substrates and other device components, light can be directed into a device of configuration 5 from the anode or the cathode side. If none of the substrates is opaque the device can be operated as a bifacial device, i.e. it can collect and convert light impinging from the anode and the cathode side. Alternatively, one of the substrates can be opaque such as optionally insulated steel, aluminium, nickel, molybdenum or concrete.

For substantially undoped light absorbers aᵢ, preferred device configuration 5, not including electrical contacts, considering optional electron blocking (p or p⁺) and/or electron blocking layers (n or n⁺), can be described as:

(p⁽⁺⁾/aᵢ/(n⁽⁺⁾) [9];

where parentheses indicate optional elements or optionally high doping levels.

In an alternative embodiment according to the present invention, a certain degree of light absorber n-doping (aₙ) or p-doping (aₚ) may be beneficial. Considering optional hole blocking (p or p⁺) and/or electron blocking layers (n or n⁺), alternative device configuration 5, not including electrical contacts, can be described as:

(p⁽⁺⁾)/aₙ or aₚ/(n⁽⁺⁾) [10]

Any number of solar devices according to any device configuration disclosed hereinabove can be connected, in series and/or parallel to form a solar panel. Additionally, series connection can be achieved in tandem configurations where at least one contact or conductor substrate is common to two adjacent cells, thereby creating an internal series connection. p-type dense and optically transparent delafossite layers can act at the same time as internal electrical cell-to-cell contact and, on one side, directly as a substrate for the p-type hole conductor material of one of two adjacent cells. Optionally, the other side of said electrical cell-to-cell contact layer is modified by a thin, preferably dense electrically conductive and largely transparent layer with the function to adequately match the work function requirements of the other of two adjacent cells.

### EXAMPLES

### Example 1

A first batch of Ni(OH)₂ paste was made from NiCl₂.6H₂O and NaOH.Ni(OH)₂ was washed with deionised water four times. Pluronic F-127 copolymer was used as a binder in combination with Ni(OH)₂ in terpineol in a 4.6:5:13.4 weight ratio to prepare a paste. Thin Ni(OH)₂ films were obtained by spin coating. MO was formed after heat treatment at 400° C. for 30 minutes, resulting in transparent films

### Example 2

A thin TiO₂ hole blocking layer was deposited on FTO/glass by ALD, followed by a thin coating of mesoporous Ties based on diluted Dyesol 18NRT TiO₂ paste. CH₃NH₃PbI₃ was then applied to the mesoporous TiO₂ layer. Nano NiO, received from Sigma-Aldrich as a black powder. was dispersed into terpineol by mechanically stirring for 1 minute, followed by six passes in a three-roll mill. The ratio of NiO to terpineol was 1:3 wt:wt, NiO slurry was spin coated on top of the TiO₂/pervoskite layer using 2000 rpm for 20 seconds, followed by heating at 110° C., for 15 minutes. A thin layer of gold was deposited onto the NiO layer by vacuum evaporation, which resulted in a device according to configuration 2.

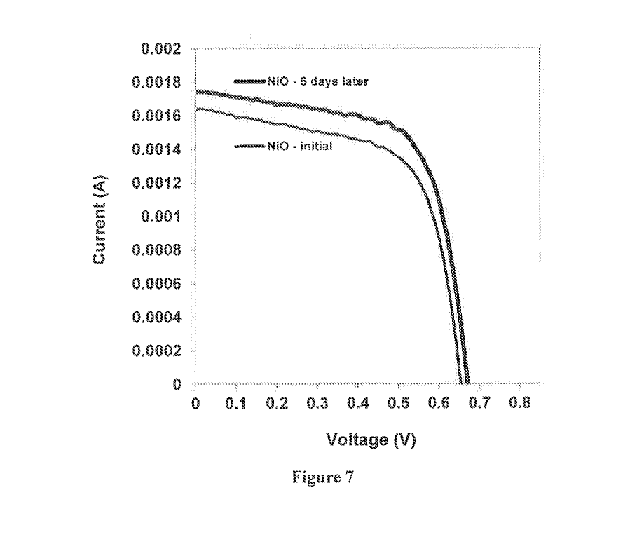

IV curves recorded immediately after assembly and after 5 days of storage, using a 0.285 cm² mask during cell testing, are shown in FIG. 7 and key performance parameters are summarised in Table 1.

TABLE 1

| Cell ID | | NiO |
|---|---|---|
| Voc (mV) | initial | 653 |
| | After 5 days | 671 |
| Jsc (mA/cm²) | initial | 5.73 |
| | After 5 days | 6.22 |
| Efficiency (%) | initial | 2.35 |
| | After 5 days | 2.74 |
| FF | initial | 0.637 |
| | After 5 days | 0.658 |

### Example 3

A thin TiO₂ hole blocking layer was deposited on FTO/glass by ALD, followed by a thin coating of mesoporous TiO₂ based on diluted Dyesol 18NRT TiO₂ paste. CH₃NH₃PbI₃ was then applied to the mesoporous TiO₂ layer. Nano NiO, received from Sigma-Aldrich as a black powder, was mixed in a 1:1 molar ratio with spiro-MeOTAD in chlorobenzene. spiro-MeOTAD concentration was 0.06M and 0.2M TBP and 0.03M LiTSFI were added to the mixture, however no cobalt dopant was employed. This slurry was spin coated on top of the TiO₂/pervoskite layer using 4000 rpm for 30 seconds in a dry air glove box. Subsequently, thin layer of gold was deposited onto the NiO/spiro-MeOTAD layer by vacuum evaporation, which resulted in a device according to configuration 3.

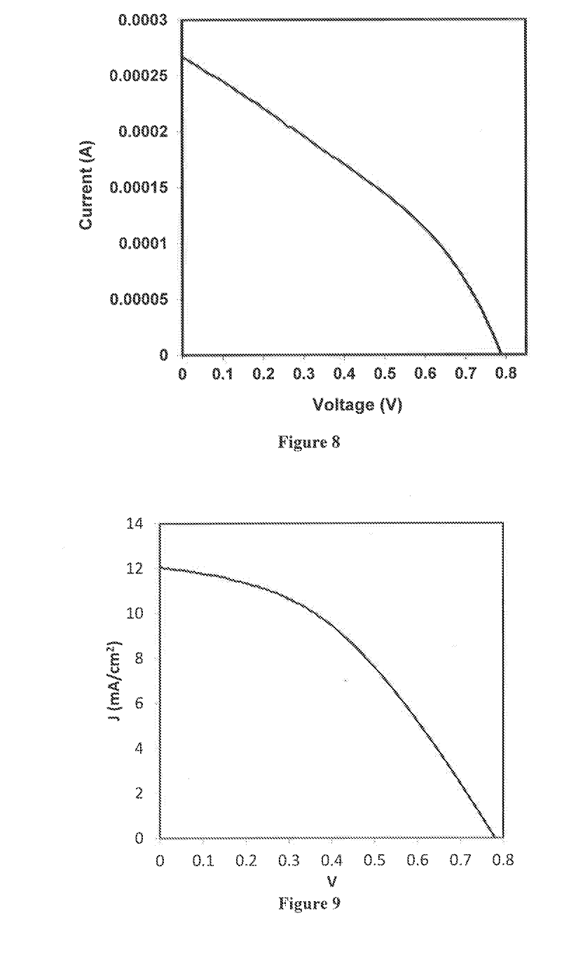

An IV curve, using a 0.159 cm² mask during cell testing, is shown in FIG. 8 and key performance parameters are summarised in Table 2.

TABLE 2

| Cell ID | NiO/spiro (1:1 mole ratio mixture) |
|---|---|
| Voc (mV) | 788 |
| Jsc (mA/cm²) | 1.68 |
| Efficiency (%) | 0.75 |
| FF | 0.344 |

### Example 4

A thin TiO₂ hole blocking layer was deposited on FM/glass by chemical bath deposition from an aqueous TiCl₄ solution, followed by a thin coating of mesoporous TiO₂ based on diluted Dyesol 18NRT TiO₂ paste. Nano-NiO, received from inframat Advanced Materials, was mixed with terpineol and ethyl cellulose by mechanically stirring and ultrasonication to form a NiO paste. This paste was diluted 1:6 (wt:wt) with ethanol and then spin-coated onto the mesoporous TiO₂ layer, followed by heat treatment at 400° C. CH₃NH₃PbI₃ was then applied to the mesoporous TiO₂/NiO layer using a combination of solvents consisting of dimethylformamide and isopropanol. After evaporation of the solvents a first subassembly was obtained. Carbon was powder-coated on a separate piece of FTO/glass through pyrolysis of paraffin resulting in a second subassembly FTO/C (=C/FTO). Said second subassembly was then mechanically combined with first subassembly in order to create an effective electrical contact between CH₃NH₃PbI₃ and C/FTO, which resulted in another device according to configuration 2.

An IV curve, using a 0.25 cm² mask during cell testing, is shown in FIG. 9 and key performance parameters are summarised in Table 3.

TABLE 3

| Cell ID | TiO₂/NiO + carbon black on FTO |
|---|---|
| Voc (mV) | 785 |
| Jsc (mA/cm²) | 12.05 |
| Efficiency (%) | 3.88 |
| FF | 0.410 |

### Example 5

A thin NiO electron blocking layer was deposited on FTO/glass by spin-coating Ni formate solution in ethylene glycol and heat treated at 300° C. Nano-NiO, received from Inframat Advanced Materials, was mixed with terpineol and ethyl cellulose by mechanically stirring and ultrasonication to form a NiO paste. This paste was diluted 1:6 (wt:wt) with ethanol and then spin-coated onto the thin NiO electron blocking layer, followed by heat treatment at 400° C. CH₃NH₃PbI₃ was then applied to the mesoporous NiO thin film, followed by spin coating a thin layer of phenyl-C61-butyric acid methyl ester (PCBM). Subsequently, a thin layer of gold was deposited onto the PCBM layer by vacuum evaporation, which resulted in a device according to configuration 1.

Key performance parameters, based on a 0.25 cm² mask used during cell testing, are summarised in Table 4.

TABLE 4

| Cell ID | MP-NiO + PCBM/Au |
|---|---|
| Voc (mV) | 578 |
| Jsc (mA/cm²) | 10.20 |
| Efficiency (%) | 2.41 |
| FF | 0.404 |

1-32. (canceled)

33. A photovoltaic device comprising:
a region of perovskite material which is in electrical contact with a mesoporous region of a hole transport material,
wherein the hole transport material at least partially comprises an inorganic hole transport material.

34. The photovoltaic device according to claim 33, wherein the inorganic hole transport material includes an oxide hole transport material.

35. The photovoltaic device according to claim 33, wherein the inorganic hole transport material is a semiconductive material.

36. The photovoltaic device according to claim 33, wherein the inorganic hole transport material is a p-type semiconductive material.

37. The photovoltaic device according to claim 33, wherein the hole transport material at least partially comprises an organic hole transport material.

38. The photovoltaic device according to claim 33, wherein the inorganic hole transport material is provided in a layer with a thickness of between about 100 nm to about 20 μm.

39. The photovoltaic device according to claim 33, wherein the inorganic hole transport material is provided in a layer with a thickness of between about 150 nm to about 1000 nm.

40. The photovoltaic device according to claim 33, wherein the inorganic hole transport material is provided in a layer with a thickness of between about 200 nm to about 500 nm.

41. The photovoltaic device according to claim 33, wherein the inorganic hole transport material is provided in a layer with a thickness of between about 10 nm to about 500 nm.

42. The photovoltaic device according to claim 33, wherein the inorganic hole transport material includes NiO, Cu₂O, CuO, CuZO₂, with Z including, but not limited to Al, Ga, Fe, Cr, Y, Sc, rare earth elements or any combination thereof, AgCoO₂ or other oxides, including delafossite structure compounds.

43. The photovoltaic device according to claim 33, wherein the perovskite material is of a formulae A₁₊ₓMX_{3-z}, ANX_{4-z}, A₂MX_{4-z}, A₃M₂X_{7-2z} or A₄M₃X_{10-3z}.

44. The photovoltaic device according to claim 43, wherein M is a mixture of monovalent and trivalent cations.

45. The photovoltaic device according to claim 33, wherein the region of perovskite material comprises additives containing surface attaching groups including, but not limited to, carboxylic or phosphonate groups.

46. The photovoltaic device according to claim 33, wherein the perovskite material includes a homogeneous or heterogeneous mixture or layer-by-layer or side-by-side combination of two or more perovskite materials.

47. The photovoltaic device according to claim 33, wherein the photovoltaic device comprises a cathode contact layer.

48. The photovoltaic device according to claim 47, wherein the cathode contact layer comprises carbon.

49. The photovoltaic device according to claim 47, wherein the cathode contact layer comprises one of aluminum, nickel, copper, molybdenum or tungsten.

50. The photovoltaic device according to claim 47, further including an electron blocking layer between the region of the hole transport material and the cathode contact layer.

51. The photovoltaic device according to claim 47, further including an electron blocking layer between the region of perovskite material and the cathode contact layer.

52. The photovoltaic device according to claim 33, further including a scaffold layer which provides a high surface area substrate for the perovskite material.

53. The photovoltaic device according to claim 33, wherein the photovoltaic device comprises an anode contact layer.

54. The photovoltaic device according to claim 53, further including a hole blocking layer between a scaffold layer and the anode contact layer.

55. The photovoltaic device according to claim 53, further including a hole blocking layer between the region of perovskite material and the anode contact layer.

56. The photovoltaic device according to claim 52, further including a polymeric or a ceramic porous separator layer between the region of the hole transport material and the scaffold layer.

57. The photovoltaic device according to claim 33, in which the perovskite material is intermixed with at least a region of one of a scaffold, a porous separator layer or the hole transport material.

58. The photovoltaic device according to claim 33, in which the perovskite material is intermixed with at least a region of one of a scaffold, a porous separator layer, the hole transport material or a cathode contact layer.

59. The photovoltaic device according to claim 33, in which at least a region of the hole transport material is intermixed with at least a region of a cathode contact layer and the perovskite material is intermixed with at least a region of one of a scaffold, a porous separator layer, the intermixed hole transport material or a cathode contact layer.

60. The photovoltaic device according to claim 33, wherein the photovoltaic device comprises a substrate.

61. The photovoltaic device according to claim 60, wherein the substrate is a metal or metal foil.

62. A method of forming a photovoltaic device according to claim 33, including the steps of:
preparing first and second sub-assemblies;
applying the perovskite material, as a liquid preparation, to at least one of the subassemblies; and
bringing the subassemblies together with one another.

63. The method according to claim 62, wherein one of the first and the second sub-assemblies comprises a substrate, optionally an electron blocking layer, a carbon-based cathode contact layer and optionally a region of hole transport material.

64. The method according to claim 62, wherein one of the first and the second sub-assemblies comprises a substrate, optionally an electron blocking layer, a region of hole transport material and optionally a porous separator layer.
